(19) United States
(12) Patent Application Publication
(10) Pub. No.: US 2009/0046519 A1
(43) Pub. Date: Feb. 19, 2009

(54) METHOD, DEVICE AND SYSTEM FOR CONFIGURING A STATIC RANDOM ACCESS MEMORY CELL FOR IMPROVED PERFORMANCE

(75) Inventors: Alice Wang, Richardson, TX (US); David Scott, Plano, TX (US); Sumanth Gururajarao, Dallas, TX (US); Gordon Gammie, Plano, TX (US); Sudha Thiruvengadam, Austin, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/839,464

(22) Filed: Aug. 15, 2007

(51) Int. Cl. G11C 5/14

(52) U.S. Cl. 365/189.09

(57) ABSTRACT

A computer-implemented method of configuring a static random access memory (SRAM) bit cell for operation, an adaptive biasing device and semiconductor wafer testing system. In one embodiment, the method includes: (1) determining a performance characteristic of the SRAM bit cell on a wafer, (2) comparing the performance characteristic to a target and (3) configuring biasing circuitry associated with the SRAM bit cell based on the comparing.

### TECHNICAL FIELD OF THE INVENTION

The invention is directed, in general, to computer memory and, more specifically, to improving performance of static random access memory (SRAM).

### BACKGROUND OF THE INVENTION

A typical SRAM device is designed to store many thousands of bits of information. These bits are stored in individual cells commonly referred to as bit cells. The bit cells are organized into rows and columns on a semiconductor substrate to form an SRAM array. A typical bit cell architecture, known as the “6T” cell, includes six metal-oxide semiconductor (MOS) transistors. Four transistors defining an SRAM cell core or memory element are configured as cross-coupled CMOS inverters, which act as a bi-stable circuit that indefinitely holds the state imposed onto it while powered. Each CMOS inverter includes a load or “pull-up” transistor and a driver or “pull-down” transistor. The pull-up transistor is typically a P-channel metal-oxide semiconductor (PMOS) transistor, and the pull-down transistor is typically an N-channel metal-oxide semiconductor (NMOS) transistor. The outputs of the two inverters are in opposite states, except during transitions from one state to another. Two additional transistors are known as “pass gate” transistors, which provide access to the cross-coupled inverters during a read operation (herein referred to as a READ) or write operation (herein referred to as a WRITE). The gate inputs of the pass transistors are typically connected in common to a “word line” (WL). The drain of one pass gate transistor is connected to a “bit line”, while the drain of the other pass gate transistor is connected to the logical complement of the bit line. During a READ, a read current, I_{READ}, traverses from a bit line through a pass transistor and through a NMOS or PMOS transistor of the bit cell depending on the content, a logical 1 or 0, of the SRAM bit cell.

The SRAM arrays are typically constructed on wafers of a semiconductor substrate. The semiconductor wafers are divided into sections referred to as dies with each die including a designated number of SRAM arrays. During production, the semiconductor substrate, (e.g., silicon) is often inconsistently manufactured. Extremes in manufacturing process variations, sometimes called “process corners,” often result in “weak” and “strong” areas on the semiconductor substrate commonly referred to as “weak silicon” and “strong silicon.” Thus, the performance of bit cells in an SRAM array may vary with respect to the condition of the semiconductor substrate where each bit cell is located. The performance of bit cells in the areas of weak silicon may not meet nominal operating requirements.

As such, an SRAM array may be biased to improve performance thereof when operating. For example, forward body biasing (FBB) of the NMOS transistors of SRAM bit cells in an SRAM array may be employed during a WRITE to improve performance of the bit cells. FBB reduces the threshold voltage of the NMOS transistors and improves the robustness for writing to bit cells, commonly referred to as V_{TRIP}.

While improving V_{TRIP}, FBB can adversely affect the Static Noise Margin (SNM) of the bit cells. SNM indicates the stability of a bit cell during a READ. Accordingly, what is needed in the art is a method and system to improve robustness of SRAM bit cells without degrading SNM.

### SUMMARY OF THE INVENTION

To address the above-discussed deficiencies of the prior art, the invention provides a computer-implemented method of configuring a static random access memory (SRAM) bit cell for operation, an adaptive biasing device and semiconductor wafer testing system. In one embodiment, the method includes: (1) determining a performance characteristic of the SRAM bit cell on a wafer, (2) comparing the performance characteristic to a target and (3) configuring biasing circuitry associated with the SRAM bit cell based on the comparing.

In another aspect, the invention provides the adaptive biasing device. In one embodiment, the adaptive biasing device includes: (1) a characteristic sensor configured to determine a performance characteristic of an SRAM bit cell on a wafer, (2) a comparator configured to compare the performance characteristic to a target and (3) a bias selector configured to bias the SRAM bit cell based on the compare.

In yet another aspect, the invention provides the adaptive biasing device. In one embodiment, the semiconductor wafer testing system includes: (1) a wafer probe configured to provide electrical access to SRAM arrays on a semiconductor wafer, (2) a wafer positioner configured to align the semiconductor wafer to enable access between contacts on the semiconductor wafer and contact points of the wafer probe and (3) a wafer tester configured to determine electrical parameters of the SRAM arrays via the wafer probe, the wafer tester including an adaptive biasing device. The wafer tester includes: (3A) a characteristic sensor configured to determine a performance characteristic of SRAM bit cells of the SRAM arrays, (3B) a comparator configured to compare the performance characteristic to a target and (3C) a bias selector configured to selectively bias the SRAM bit cells based on the compare.

### BRIEF DESCRIPTION OF THE DRAWINGS

For a more complete understanding of the invention, reference is now made to the following descriptions taken in conjunction with the accompanying drawings, in which:

FIG. 1 illustrates an embodiment of a semiconductor wafer testing system constructed according to the principles of the invention;

FIGS. 2A and 2B illustrate graphs representing data that may be used to obtain targets according to the principles of the invention;

FIG. 3 illustrates an embodiment of a method of configuring a static random access memory (SRAM) bit cell for operation carried out according to the principles of the invention.

### DETAILED DESCRIPTION

The invention adaptively applies biasing to selected SRAM bit cells of SRAM arrays based on parametric measurements of the SRAM bits cells. As such, the invention considers process variations of manufactured SRAM arrays to improve the performance of SRAM bit cells manufactured at a weak process corner without compromising the stability of SRAM bit cells manufactured at a strong process corner. The biasing may be forward body biasing.

The parametric measurements may include the drive currents of the SRAM bit cell transistors. Thus, the NMOS and PMOS drive currents may be determined. The parametric measurement can be compared to a target to determine if biasing should be applied to a certain SRAM bit cell. The target can be based on historical data. The parametric measurements and subsequent biasing may be determined during wafer probing of a manufactured wafer.

Alternatively, determining if biasing should be applied to a certain SRAM bit cell may be based on target reference values associated with logic oscillators employed in a “reflex” module. A reflex module may be implemented within any chip (i.e., load) or circuit system to compensate for at least one of the various factors that adversely affect the speed of a circuit path (e.g., critical path) on the chip. The target reference values can be performance values provided by a manufacturer or another entity. The logic oscillators may be a NAND ring oscillator or a NOR ring oscillator. A reflex module can use the target reference values to determine if biasing is needed. If so, the reflex module can perform the necessary calibration to apply the needed biasing. More information about reflex modules can be found in U.S. patent application Ser. No. 11/213,477, entitled “ADAPTIVE VOLTAGE CONTROL AND BODY BIAS FOR PERFORMANCE AN ENERGY OPTIMIZATION,” which is incorporated herein by reference in its entirety.

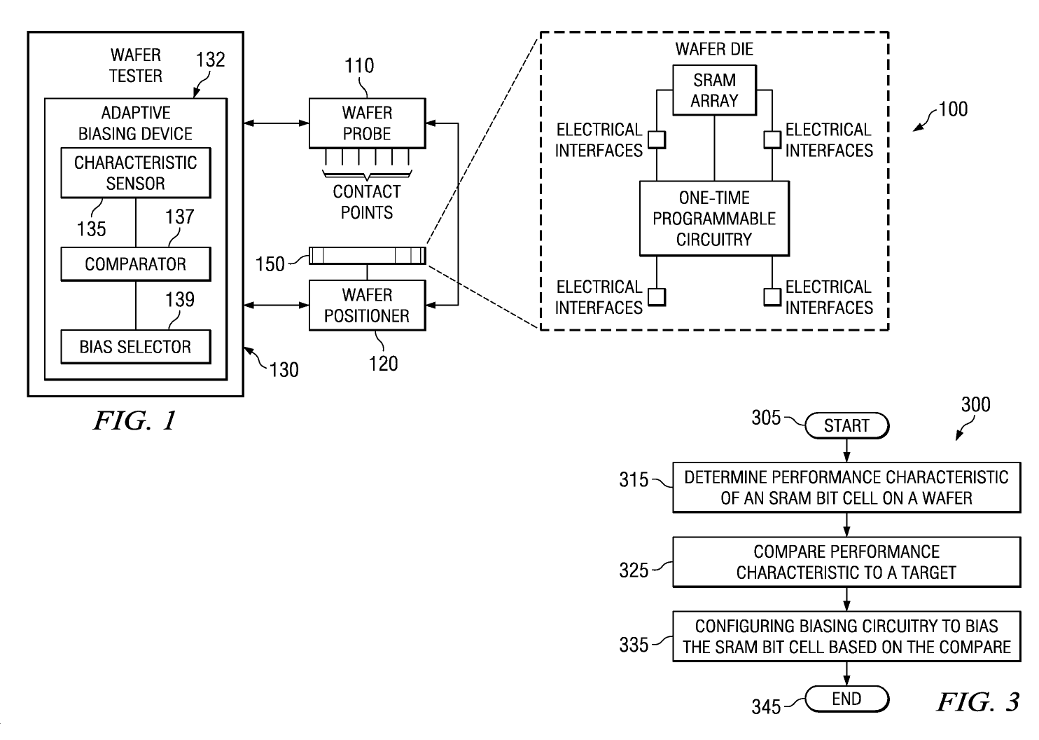

FIG. 1 illustrates a block diagram of an embodiment of a semiconductor wafer testing system 100 constructed according to the principles of the invention. The semiconductor wafer testing system 100 includes a wafer probe 110, a wafer positioner 120 and a wafer tester 130.

A semiconductor wafer 150 is also illustrated along with the semiconductor wafer testing system 100. The semiconductor wafer 150 includes multiple dies of SRAM arrays. Each of the SRAM arrays including multiple rows and columns of SRAM bit cells. Additionally, each die includes multiple electrical interfaces that provide access to the SRAM bit cells. The electrical interfaces may be contact pads that are located by design to provide access to the SRAM bit cells during operation and during testing. The semiconductor wafer 150 also includes one-time programmable circuitry electrically coupled to the SRAM arrays and the electrical interfaces. The one-time programmable circuitry may be an arrangement of fuses that are programmed by being blown in response to a voltage selectively applied at the electrical interfaces. The one-time programmable circuitry, for example, may be electronic fuses such as eFUSEs developed by IBM®.

The wafer probe 110 is configured to provide electrical access to SRAM arrays on the semiconductor wafer. The wafer probe 110 includes contact points that are designed to couple with the electrical interfaces on the semiconductor wafer. The wafer positioner 120 is configured to align the semiconductor wafer 150 to enable access between the electrical interfaces of the semiconductor wafer 150 and the contact points of the wafer probe 110. The wafer positioner 120 may align the semiconductor wafer 150 with the wafer probe 110 employing various means including a laser. The wafer positioner 120 and the wafer probe 110 may be a typical wafer positioner and wafer probe used in conventional semiconductor wafer testing.

The wafer tester 130, coupled to the wafer probe 110 and the wafer positioner 120, is configured to determine electrical parameters of the SRAM arrays via the wafer probe 110. The wafer tester 130 may be implemented as dedicated hardware. Additionally, the wafer tester 130 may be a general purpose computer that is operated according to a series of operating instructions, or software. In some embodiments, the wafer tester 130 may be implemented as a combination of dedicated hardware, general purpose hardware and software. The wafer tester 130 includes an adaptive biasing device 132. One skilled in the art will understand that the wafer tester 130 may also include additional components or devices for testing a semiconductor wafer that are not pertinent to the invention.

The adaptive biasing device 132 is implemented as a series of operating instructions representing algorithms that control the selective biasing of SRAM bit cells. The adaptive biasing device 132 includes a characteristic sensor 135, a comparator 137 and a bias selector 139. The characteristic sensor 135 is configured to determine at least one performance characteristic of at least one SRAM bit cell of the SRAM arrays. The SRAM bit cell may be used to represent an SRAM array. The characteristic sensor 135 determines the performance characteristic by applying various voltages and currents to an SRAM array on the semiconductor wafer 150 via the contact points of the wafer probe and, via the contact points, measuring the response of the SRAM bit cells and the SRAM array. The characteristic sensor 135 is configured to determine the performance characteristic of SRAM bit cells on a die-by-die basis.

Each of the SRAM bit cells includes a PMOS transistor and a NMOS transistor. In one embodiment, the characteristic sensor 135 measures the drive current of the NMOS transistor and this is used as the performance characteristic. In other embodiments, the characteristic sensor 135 may measure a drive current of the PMOS transistor and this may be used as the performance characteristic. The characteristic sensor 135 may determine multiple performance characteristics to be used. Regardless of the performance characteristic that is measured, each one is a reflection of the manufacturing process of the SRAM bit cells.

The comparator 137 is configured to compare the performance characteristic to a target. The target may be based on historical operational data of SRAM bit cells. Targets can vary based on process technology and devices. Historical operating data may indicate FBB of all SRAM bit cells in an SRAM array results in an SNM outside of a desired performance specification for some of the SRAM bit cells. Performance analysis can associate a performance characteristic of these SRAM bit cells to determine when FBB is needed and when FBB is not needed. For example, if the NMOS drive current is less than a designated target, applying a FBB can result in an I_{READ} improvement of at least approximately 12.5% without sacrificing SNM. However, if the NMOS drive current is greater than or equal to the designated target and the FBB is applied, then SNM becomes an issue. Accordingly, in some embodiments, the target may be the desired value of a NMOS drive current. In other embodiments, the target may be a ratio of the desired values of NMOS and PMOS drive currents.

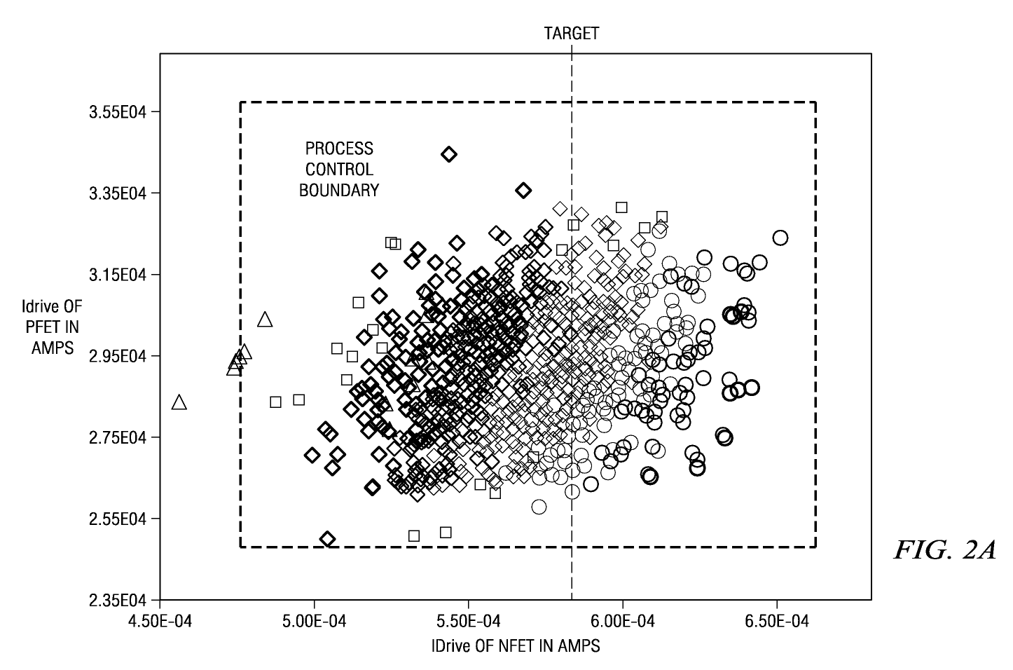

FIGS. 2A and 2B illustrate graphs representing data that may be used to obtain targets according to the above examples. FIGS. 2A and 2B represent SNM of bit cells in volts versus the drive current in amps of a PMOS transistor of the bit cell (y axis) and the drive current in amps of a NMOS transistor of the bit cell (x axis). In FIG. 2A, the target is the NMOS drive current. An acceptable SNM value according to, for example, historical data, is determined. Based thereon, a corresponding NMOS drive current is selected as a NMOS drive current target. In FIG. 2B, the target is the ratio of NMOS and PMOS drive currents.

In both graphs, the data points in the graph, (e.g., the triangle, the diamond, the square, etc.) represent a SNM value within a range between 0.1 volts to 0.216 volts. Each particular shape reflects a certain range between the 0.1 volts to 0.216 volts with the bolder data points having a higher SNM than the other similar-shaped data points. The process control boundary denotes the boundary of die that can be manufactured. Typically, a die will not be shipped if the NMOS and PMOS drive currents fall outside of the process control boundary.

The bias selector 139 is configured to selectively bias the SRAM bit cells based on the comparison results from the comparator 137. Continuing the above example, the bias selector 139 can selectively blow designated fuses of the one-time programmable circuitry to apply a forward body bias to SRAM bit cells that have a NMOS drive current less than the target. The amount of the forward body bias may be determined based on historical data and be device or process dependent. Those SRAM bit cells having a NMOS drive current equal to or greater than target would not be forward body biased. In one embodiment, the bias selector 139 varies the amount of forward body biasing based on the performance characteristic. Thus, instead of applying the same forward body bias to each SRAM bit cell with a NMOS drive current less than the target, the amount of the forward body bias voltage would vary depending on the NMOS drive current.

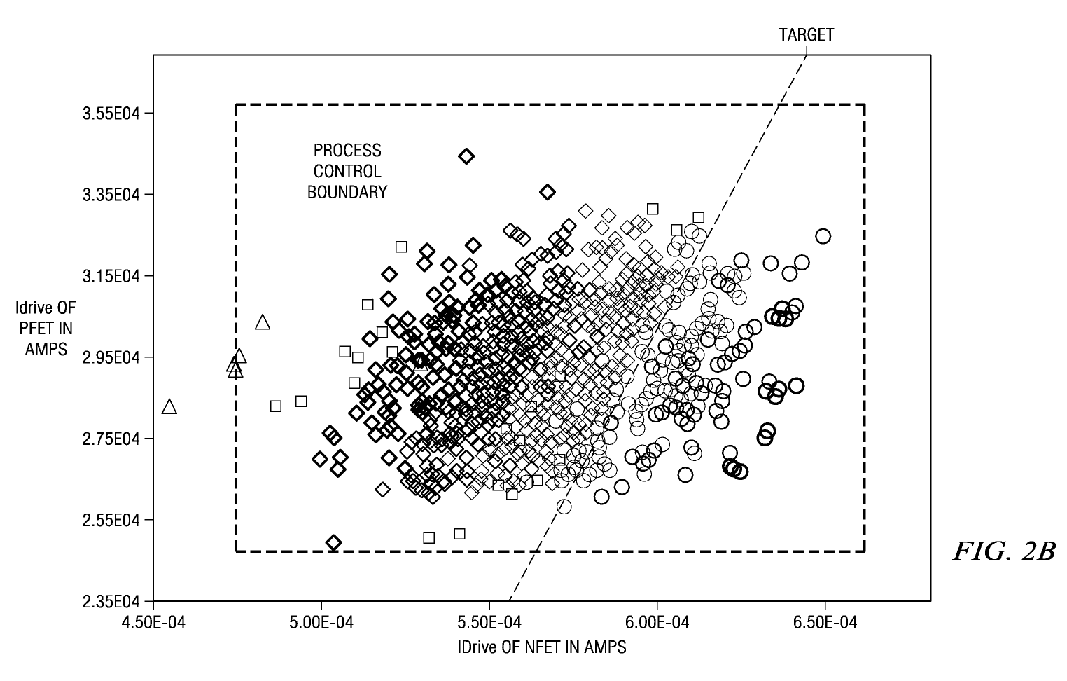

FIG. 3 illustrates an embodiment of a method 300 of configuring a SRAM bit cell for operation carried out according to the principles of the invention. The method 300 begins in a step 305 with an intent to configure an SRAM bit cell.

After beginning, a performance characteristic of an SRAM bit cell on a wafer is determined in a step 315. A single or multiple performance characteristic(s) may be determined. In some embodiments, the performance characteristic may be a drive current of a NMOS transistor. The performance characteristic may also be a drive current of a PMOS transistor. The performance characteristic may be determined via a wafer probe during wafer testing. In some embodiments, the performance characteristic may be determined for multiple SRAM bit cells of multiple SRAM arrays on the wafer. Step 315, therefore, may be performed on a die to die basis with respect to the wafer.

The performance characteristic is then compared to a target in step 325. The target may be a single value or vary based on a ratio. The target may be determined based on historical data and desired operational parameters of SRAM bit cells.

After comparing, biasing circuitry associated with the SRAM bit cell is configured to bias the SRAM bit cell based on the comparing in a step 335. In some embodiments, the biasing circuitry is configured to forward body bias the SRAM bit cell. The biasing circuitry may be configured to bias multiple SRAM bit cells. The amount of bias may be constant or may vary depending on the performance characteristic. In some embodiments, the amount of bias may be proportionate to the performance characteristic. The biasing may be performed by tripping designated fuses of one-time programmable circuitry coupled to the SRAM bit cells. After biasing, the method 300 ends in a step 345.

Those skilled in the art to which the invention relates will appreciate that other and further additions, deletions, substitutions and modifications may be made to the described embodiments without departing from the scope of the invention.

What is claimed is:

1. A computer-implemented method of configuring a static random access memory (SRAM) bit cell for operation, comprising:
determining a performance characteristic of said SRAM bit cell on a wafer;
comparing said performance characteristic to a target; and
configuring biasing circuitry associated with said SRAM bit cell based on said comparing to bias said SRAM bit cell.

2. The method as recited in claim 1 wherein said bias is a forward body bias.

3. The method as recited in claim 1 wherein said performance characteristic is a drive current of a NMOS transistor of said SRAM bit cell.

4. The method as recited in claim 1 wherein said target is a desired value of a drive current of an NMOS transistor of a representative SRAM bit cell.

5. The method as recited in claim 1 wherein said target is a ratio of desired values of drive currents of a NMOS transistor and a PMOS transistor of a representative SRAM bit cell.

6. The method as recited in claim 1 wherein said wafer includes multiple dies and said method is performed on each of said multiple dies.

7. The method as recited in claim 1 wherein said biasing circuitry is one-time programmable circuitry coupled to said SRAM bit cell and said configuring includes blowing at least one fuse of said one-time programmable circuitry to bias said SRAM bit cell.

8. An adaptive biasing device, comprising:
a characteristic sensor configured to determine a performance characteristic of an SRAM bit cell on a wafer;
a comparator configured to compare said performance characteristic to a target; and
a bias selector configured to bias said SRAM bit cell based on said compare.

9. The adaptive biasing device as recited in claim 8 wherein said bias selector is configured to forward body bias said SRAM bit cell.

10. The adaptive biasing device as recited in claim 8 wherein said performance characteristic is a drive current of a NMOS transistor of said SRAM bit cell.

11. The adaptive biasing device as recited in claim 8 wherein said target is a desired value of a drive current of an NMOS transistor of a representative SRAM bit cell.

12. The adaptive biasing device as recited in claim 8 wherein said target is a ratio of desired values of drive currents of a NMOS transistor and a PMOS transistor of a representative SRAM bit cell.

13. The adaptive biasing device as recited in claim 8 wherein at least one of said characteristic sensor, said comparator and said bias selector are included within a wafer probe machine.

14. The adaptive biasing device as recited in claim 8 wherein said wafer includes multiples dies of SRAM bit cells and said characteristic sensor is configured to determine said performance characteristic of multiple bit cells on a die-by-die basis.

15. The adaptive biasing device as recited in claim 8 wherein said bias selector is configured to program one-time programmable circuitry coupled to said SRAM bit cell to bias said SRAM bit cell based on said compare.

16. A semiconductor wafer testing system, comprising:
a wafer probe configured to provide electrical access to SRAM arrays on a semiconductor wafer;
a wafer positioner configured to align said semiconductor wafer to enable access between contacts on said semiconductor wafer and contact points of said wafer probe; and
a wafer tester configured to determine electrical parameters of said SRAM arrays via said wafer probe, said wafer tester including an adaptive biasing device, comprising:
a characteristic sensor configured to determine a performance characteristic of SRAM bit cells of said SRAM arrays;
a comparator configured to compare said performance characteristic to a target; and
a bias selector configured to selectively bias said SRAM bit cells based on said compare.

17. The semiconductor wafer testing system as recited in claim 16 wherein said bias selector is configured to selectively forward body bias said SRAM bit cells.

18. The semiconductor wafer testing system as recited in claim 16 wherein said performance characteristic is a drive current of a NMOS transistor of said SRAM bit cell.

19. The semiconductor wafer testing system as recited in claim 16 wherein said target is a desired value of a drive current of an NMOS transistor of a representative SRAM bit cell.

20. The semiconductor wafer testing system as recited in claim 16 wherein said target is a ratio of desired values of drive currents of a NMOS transistor and a PMOS transistor of a representative SRAM bit cell.

21. The semiconductor wafer testing system as recited in claim 16 wherein said semiconductor wafer includes multiples dies of SRAM arrays and said characteristic sensor is configured to determine said performance characteristic of SRAM bit cells on a die-by-die basis.

22. The semiconductor wafer testing system as recited in claim 16 wherein said bias selector is configured to program one-time programmable circuitry coupled to said SRAM array to selectively bias said SRAM bit cells based on said compare.
